(19) United States
(12) Patent Application Publication
(10) Pub. No.: US 2011/0024181 A1
(43) Pub. Date: Feb. 3, 2011

(54) SYSTEM AND METHOD FOR PROTECTION AGAINST SKIMMING OF INFORMATION FROM CONTACTLESS CARDS

(76) Inventor: Simon Phillips, York (GB)

Correspondence Address: BUCKLEY, MASCHOFF & TALWALKAR LLC, 50 LOCUST AVENUE, NEW CANAAN, CT, 06840, US

(21) Appl. No.: 12/884,725

(22) Filed: Sep. 17, 2010

Related U.S. Application Data
(63) Continuation-in-part of application No. 11/865,209, filed on Oct. 1, 2007.
Application No. 11/865,209 is a continuation of application No. PCT/US06/12053, filed on Apr. 3, 2006.
Application No. PCT/US06/12053 is a continuation-in-part of application No. 11/964,938, filed on Dec. 27, 2007, now abandoned.
(60) Provisional application No. 60/667,864, filed on Apr. 1, 2005.

(51) Int. Cl. H05K 9/00

(52) U.S. Cl. 174/350

(57) ABSTRACT

Contactless payment cards with on-card microchips are transported in mailers with RF shielding. The RF shielding is designed to prevent communication with and skimming of information from the contactless cards enclosed in the mailers while in transit.

### CROSS-REFERENCE TO RELATED APPLICATIONS

This application is a continuation-in-part of U.S. nonprovisional patent application Ser. No. 11/865,209, filed on Oct. 1, 2007, which is a continuation of application no. PCT/US06/12053, filed on Apr. 3, 2006, and which claims the benefit of U.S. provisional patent application No. 60/667,864 filed on Apr. 1, 2005; this application is also a continuation-in-part of U.S. nonprovisional patent application Ser. No. 11/964,938, filed Dec. 27, 2007; the above-recited application Ser. Nos. 11/865,209; PCT/US06/12053; 60/667,864 and 11/964,938 are hereby incorporated by reference herein in their entirety.

### BACKGROUND OF THE INVENTION

This invention relates to payment cards that are used for mailing contactless payment transactions. In particular, the invention relates to techniques for fraud prevention in proximity, contactless or smart card payment systems.

Payment cards such as credit or debit cards are ubiquitous. For decades, such cards have included magnetic stripe cards on which the relevant account number is stored. To consummate a purchase transaction with such a card, the card is swiped through a magnetic stripe reader that is part of a point of sale (POS) terminal. The reader reads the account number from the magnetic stripe. The account number is then used to route a transaction authorization request that is initiated by the POS terminal.

In pursuit of still greater convenience and more rapid transactions at POS terminals, payment cards have more recently been developed that allow the account number to be automatically read from the card by radio frequency communication between the card and a so-called “proximity reader” that may be incorporated with the POS terminal. In such cards, often referred to as “proximity payment cards”, a radio frequency identification (RFID) integrated circuit (IC, often referred to as a “chip”) is embedded in the card body. A suitable loop antenna, formed of one or more turns of a conductive material, is also embedded in the card body. There are conductive connections between the antenna and the RFID chip to allow the chip to receive and transmit data by RF communication via the antenna. In typical arrangements, the RFID chip is powered from an interrogation signal that is transmitted by the proximity reader and received by the card antenna.

MasterCard International Incorporated, the assignee hereof, has established a widely-used standard, known as “PayPass”, for interoperability of proximity payment cards and proximity readers.

Conventional practices call for the loop antenna in a proximity payment card to generally follow the outline of the card body in order to maximize the planar extent of the antenna. All other things being equal, the larger the extent of the antenna, the more reliable is the coupling between the proximity payment card and the proximity reader.

The present inventor has recognized a need to provide enhanced security for proximity payment devices. One issue the inventor has addressed is the potential for proximity payment cards to be read by unauthorized persons who have the intention of collecting account number for fraudulent purposes.

Proximity payments are used in situations where, although the purchaser is present, it is useful or at least more convenient to be able to make a payment without having to make physical contact with the vendor/payee. The purchaser, for example, may use a contactless “smart card” to make a proximity payment without having to manually swipe a card through a conventional point-of-sale device (i.e., a magnetic strip card reader). An exemplary contactless smart card is a MasterCard PayPass™ card. This card is an enhanced payment card that features a hidden embedded microprocessor chip and antenna (i.e. a miniature Radio Frequency (RF) transceiver chip and an antenna). The MasterCard PayPass system provides a purchaser with a simpler way to pay. The purchaser can simply tap or wave his or her MasterCard PayPass payment card on a specially equipped merchant terminal that then transmits payment details wirelessly using radio frequency signals, eliminating the need to swipe the card through a reader. Account details are communicated directly to the specially equipped merchant terminal and are then processed through MasterCard's highly trusted acceptance network. Moments after the purchaser taps the terminal with his or her MasterCard PayPass card, he/she receives payment confirmation and is on his/her way.

Proximity payment systems based on smart cards (such as MasterCard PayPass) may be advantageously implemented in traditional cash-only environments where speed is essential, (e.g., quick serve and casual restaurants, gas stations and movie theaters). Purchaser information, which may be stored in a microchip on the smart card, is sent directly from the microchip to a point-of-sale (POS) device or other wireless reader device, which may be up to about 10 cms away. Proximity payments also may be made using other payment devices (e.g., a mobile phone, PDA, or handheld computer), which are suitably configured to carry a microchip that stores and retransmits stored or processed account information when required. Common industry infrared or wireless protocols (e.g., Bluetooth) may govern communication between the payment device and the vendor/payee's wireless reader or POS device.

As with electronic payment transactions conducted over the Internet and other e-commerce transactions, both parties to a proximity payment transaction will have security concerns. Payers need reassurance that the vendor/payees are not unscrupulous criminals who will misuse payer information, the vendor/payees need to know that the payers are legitimate and both parties need to know that unauthorized third parties cannot intercept the transaction information. A number of techniques, which address at least some of these security concerns, are available. Data encryption techniques, for example, can be used to secure transaction information during transmission.

The proximity and smart card payment systems take advantage of the new on-card chip technology to deploy cardholder verification methods to make secure transactions. Purchases made with the cards can be verified, for example, by use of a personal identification number, or PIN. The proximity and smart cards aim to cut fraud by including an on-card microchip, which can store more information than the usual magnetic strips, and also by having users verify transactions by keying in a personal identification number (PIN) rather than signing a receipt. However, as with any technology, the security provided by on-card chip technology is not infallible. Fraudsters can find new ways of illegally accessing cardholder information to breach security.

Consideration is now directed toward improving schemes for safeguarding cardholder information to prevent, for example, fraudulent use of stolen or lost payment cards. In particular, attention is directed to securing the information contained in proximity, contactless or smart payment cards.

### BRIEF DESCRIPTION OF THE DRAWINGS

FIG. 1 is a schematic plan view of a mailable assembly which includes a proximity payment card and which is provided in accordance with aspects of the present invention.

FIG. 2 is a schematic side view of the mailable assembly of FIG. 1.

FIG. 3 is a schematic plan view of the proximity payment card shown in FIGS. 1 and 2.

FIG. 4 is a schematic sectional view of a shielding label which is part of the mailable assembly of FIGS. 1 and 2.

FIG. 5 is a view similar to FIG. 2, showing an alternative embodiment of the mailable assembly.

FIG. 6 is a flow chart that illustrates aspects of a method provided in accordance with some embodiments.

FIG. 7 is an illustration of an exemplary mailer having RF-shielding material, which is designed to prevent intruding RF-signals from communicating with an enclosed payment card having an on-card microchip, in accordance with aspects of the invention.

### DETAILED DESCRIPTION

In general, and for the purpose of introducing concepts of embodiments of the present invention, an assembly in which a proximity payment card is mailed to the intended holder thereof also includes a protective label that is adhered to the face of the card and shields the card antenna to prevent unauthorized reading of the card while it is in transit. According to other aspects, the size of the card antenna is reduced, and the antenna is located within the card body, so that the protective label may be the same size and in the same location on the card as labels that are applied to payment cards in conventional card fulfillment operations.

In accordance with other aspects of the present invention, a system and a method are provided for safeguarding cardholder information stored in proximity, contactless or smart cards. The system and a method involve transporting the cards in RF-shielded environments that prevent unauthorized RF intrusion or access to the on-card chip circuits. The invention advantageously further reduces opportunities for fraud in payment-by-card systems.

The advantages of the invention may be understood with reference to counterfeiting, which is a type of card fraud that is prevalent with current electronic or paper payment systems that are based, for example, on plastic cards in which magnetic stripes or embossed structures contain cardholder information. A counterfeit card is one that has been printed, embossed or encoded without the consent or knowledge of the card issuer, or one that has been validly issued but has then been altered or recoded. A common method of counterfeiting is called skimming, in which the counterfeiters copy the information stored in the magnetic stripes on plastic cards. The counterfeiter copies the information stored in the magnetic stripe, for example, by swiping it through a small card reader. Armed with this information, the counterfeiter can then produce counterfeit cards and use them to carry out fraudulent transactions.

Proximity, contactless and smart cards in which computer chips are embedded hold more information, but in a more secure environment, than can be stored magnetic stripe cards. However, in some circumstances a thief or counterfeiter may be able to access the information stored in proximity or smart cards.

The present invention is designed to preclude skimming (i.e., stealing) of cardholder information when proximity, contactless or smart cards are in transit, for example, sent to the cardholders through public mail.

The on-card chips have electronic circuits, which exploit electromagnetic or electrostatic coupling in the radio frequency (RF) portion of the electromagnetic portion of the electromagnetic spectrum to communicate with card reader units (e.g., Point of Sale devices). A card reader unit may include an RF antenna and a transceiver. The reader unit emits radio waves, and when a proximity, contactless or smart card is placed within the range of the card reader unit, the on-card chip responds and starts sending data to the reader unit. The on-card chips themselves may come in a wide variety of sizes, shapes and forms but have common attributes; each includes low-energy broadcast circuitry, programmable data storage and operating circuitry. The on-card chips may be with and without batteries, and they can be read only or read/write. Typically, on-card chips without batteries (passive circuits) are smaller and lighter than those that are with batteries (active circuits), and less expensive. The passive on-card chip circuits are powered and activated by the reader units. In either case, when activated on-card chip circuits can broadcast stored information over radio frequency waves.

At least theoretically, it is possible for an unauthorized person or fraudster to use a card reader or similar RF device to extract cardholder information stored in an on-card chip in a manner similar to using an unauthorized magnetic stripe card reader to skim information form magnetic stripe cards. In the case of proximity, contactless or smart cards, a potential opportunity for accessing card information arises when card issuers send cards by mail to cardholders, for example, in conventional postal envelopes or mailing packages. The unauthorized person or fraudster may use a card reader or similar RF device to activate the on-chip card and extract card information while the card is in transit. The unauthorized person may literally do so without opening the envelope—possibly even while the card is still in a mailbox.

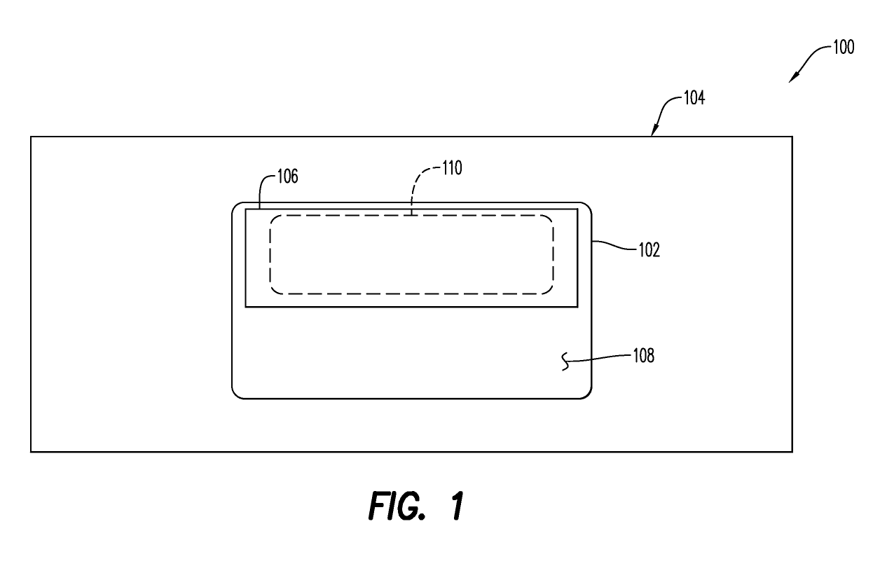

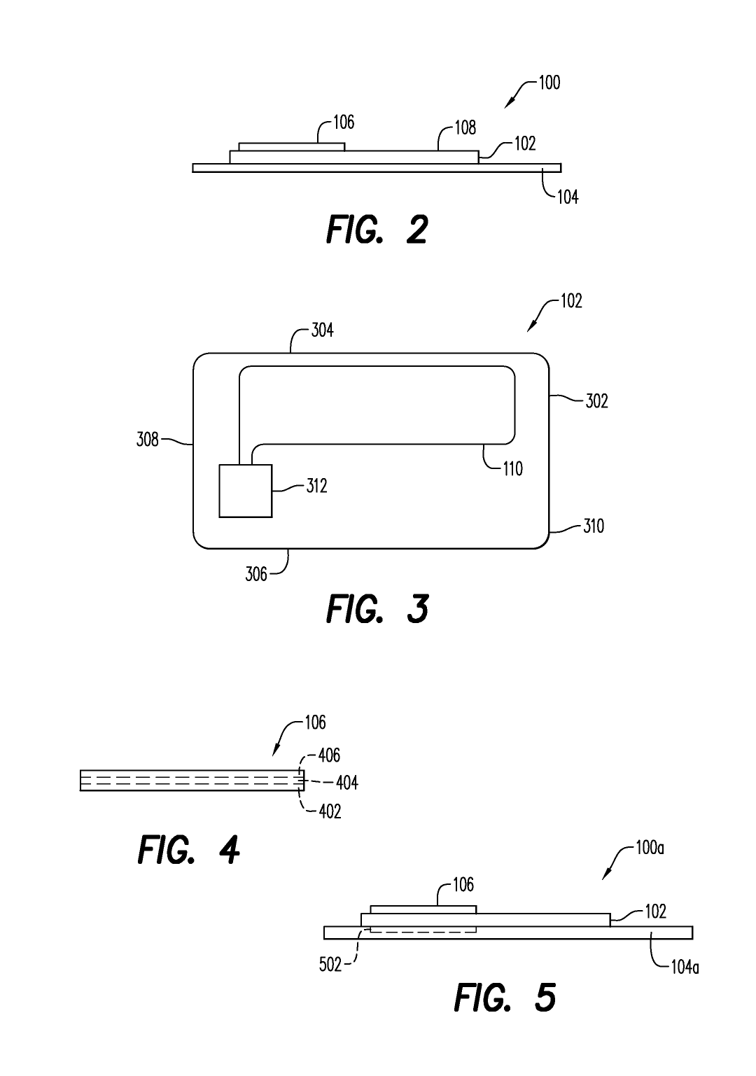

FIG. 1 is a schematic plan view of a mailable assembly 100 which includes a proximity payment card 102 and which is provided in accordance with aspects of the present invention. FIG. 2 is a schematic side view of the mailable assembly 100.

The mailable assembly 100 includes a backing sheet 104 to which the proximity payment card 102 is adhered. The mailable assembly 100 also includes a protective label 106 which is adhered to the face (front surface 108) of the proximity payment card 102.

The rounded-corner dashed line rectangle indicated at 110 in FIG. 1 substantially indicates the locus of a loop antenna which is embedded in the proximity payment card 102. The antenna 110 is also schematically shown in a somewhat different fashion in FIG. 3.

FIG. 3 is a schematic plan view of the proximity payment card 102. The proximity payment card 102 includes a plastic card body indicated by reference numeral 302 in FIG. 3. The card body 102 is generally rectangular and planar and has dimensions in accordance with the well known ID-1 standard for identification cards. Consequently, the length of the card body 302 and of the card 102 is substantially 85.6 mm and the width or height of the card body 302 and of the card 102 is substantially 53.98 mm. With these dimensions, issuance of the card may be processed using conventional identification card processing equipment. It will be observed that the card body 302 has two relatively long edges 304 and 306 and two relatively short edges 308 and 310. The long edges 304 and 306 are parallel to each other and the short edges 308 and 310 are parallel to each other.

The proximity payment card 102 also includes an RFID chip 312. The antenna 110 is coupled to the RFID chip 312 in a conventional manner to allow for the RFID chip 312 to receive power signals from, and to exchange RF communications with, proximity reader components (not shown) of POS terminals (not shown). The RFID chip 312 is embedded in the card body 302. An account number that corresponds to the account to be accessed with the proximity payment card 102 is stored in the RFID chip 312 in such a manner that the account number is transmitted from the proximity payment card 102 to a proximity reader component of a POS terminal during a conventional interaction between the proximity payment card 102 and the proximity reader.

In accordance with conventional practices, the antenna 110 may be formed of one or more loops of a conductive material, located substantially as indicated in FIGS. 1 and 3.

For reasons that will be made clear below, it is preferable that the antenna 110 have a certain geometry, certain dimensions, and be located in a certain manner within the card body 302. The preferred antenna geometry, dimensions and location as described below are premised on the card body having the above-mentioned ID-1 standard dimensions.

It is preferred then that the antenna 110 be substantially rectangular with a length of substantially 70 mm and a width of 22 mm. It is preferred that the antenna 110 be located 3.5 mm from the top edge 304 of the card body 302 and located 7.8 mm from the side edges 308 and 310 of the card body 302. With this geometry, set of dimensions and location within the card body 302, the antenna 110 may achieve a preferred accommodation between two competing objectives. The first objective is the conventional objective of having the antenna as large in extent as is practically possible. The second objective, which is not believed to have been recognized in the prior art, is to accommodate the antenna to being shielded by a label to be applied to the proximity payment card 102 before the proximity payment card 102 is mailed to the prospective card holder. In particular, the second objective calls for the label to be provided in accordance with a standard size for such labels, and for the label to be applied to the proximity payment card on a customary location on the proximity payment card. By achieving the second objective, the present invention may allow conventional processing equipment and card processing procedures to be employed while providing enhanced security for proximity payment cards while the same are in transit from the card issuer to the prospective card holder. In other words, the proposed preferred antenna geometry, dimensions and location may essentially eliminate any disruption to card issuance procedure from a proposed new security feature, since card issuers would not be required to purchase new card processing equipment, nor to modify currently owned card processing equipment, nor to modify card processing procedures. The only changes required of card issuers, if the preferred proximity card embodiment is employed, are that they obtain a supply of card blanks with the antenna geometry, dimensions and location as described above in connection with FIG. 3 and that they use a label stock with an antenna shielding capability as described below. Thus the additional card security feature proposed herein may be implemented by card issuers with little additional cost.

There will now be provided a further explanation for the preferred antenna geometry, dimensions and location. It is customary in issuing a payment card to apply a label to the payment card. The label may, for example, instruct the card holder to call a certain toll-free telephone number for the purpose of confirming receipt of, and activating, the payment card. The label often complies with a standard size, which is rectangular, 76.2 mm by 25.4 mm. The location at which the label is customarily applied to the payment card (an ID-1 card) is typically 2.54 mm from the top card edge, with a tolerance of plus or minus 0.51 mm, and 2.54 mm from either the left card edge or the right card edge, again with a tolerance of plus or minus 0.51 mm. Given this standard size of the label, and its standard location (with the above noted tolerances) on the payment card, the above-recited preferred geometry, dimensions and location of the antenna as described above in connection with FIG. 3 result in the largest possible extent of the antenna consistent with having the antenna substantially completely covered by the label. (Smaller antennas may alternatively be employed, but are not preferred.)

Although not shown in the drawings, the proximity payment card may have additional features, such as a magnetic stripe that allows it to be read by POS terminal mag stripe readers. Another possible additional feature may be a paper tape on the back of the card on which the card holder may write his/her signature. Also there may be printed and/or embossed information on the card (such as payment card account number, card holder's name, etc.) and branding information such as the name and/or logo of the issuing bank and of the payment card association (e.g., MasterCard) of which the issuing bank is a member.

FIG. 4 is a schematic sectional view of the protective label 106. As shown, the label includes three layers, although there may be more or fewer than three. The lower layer 402 may be an adhesive by which the label may be adhered to the proximity payment card 102. The layer 402 may be of conventional composition. The middle layer 404 may be a conductive material such as a metal foil, suitable for shielding the antenna 110 from receiving RF radiation. The upper layer 406 may, for example, be paper or another material suitable for printing instructions to the card holder about how to activate the card.

Given the shielding layer 404 of the label 106, it will be appreciated from FIG. 1, and the position of label 106 relative to antenna 110, that the label 106 may substantially shield the antenna 106 from receiving RF radiation, and thus may protect the proximity payment card 102 from unauthorized reading while it is in transit from the card issuer to the card holder. The label may be said to “entirely overlap” the antenna in the sense that the label covers essentially the entire planar extent of the antenna (although potentially not covering the leads from the antenna to the RFID chip).

If the threat of unauthorized reading is believed to be particularly severe, then it may be desirable for the mailable assembly to provide shielding on both sides of the proximity payment card antenna. A mailable assembly 100a for that purpose is shown in schematic cross-section in FIG. 5. In the mailable assembly 100a of FIG. 5, the proximity payment card 102 and the label 106 may be the same as shown in FIGS. 1-4, but the backing sheet (reference numeral 104a in FIG. 5) may be modified so as to include a conductive layer 502, at least at the locus of the label 106 and the antenna 110 (not shown in FIG. 5). The conductive layer 502 may be suitable for shielding the antenna 110 from receiving RF radiation, and may be a metal foil, for example.

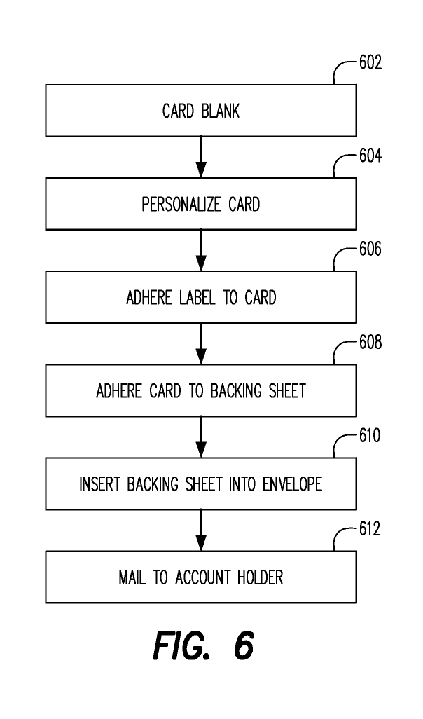

FIG. 6 is a flow chart that illustrates a process that may be performed for purposes of fulfilling an order for a proximity payment card. Except for certain features, as described hereinabove, of the proximity payment card and the label to be affixed to the card, the process of FIG. 6 may be performed in a completely conventional manner.

At 602 in FIG. 6, a proximity payment card blank is provided. Preferably the card blank has an antenna configured as described above. At 604, a procedure known as “personalization” is applied to the card blank. For the sake of concision, “personalization” should be understood to include pre-personalization. During pre-personalization, information is applied to the card that is common to all cards in the batch of cards being processed. The information may be applied by being printed and/or embossed on the card and/or loaded by RF communication into the card's RFID chip and/or magnetically stored on the card's mag stripe (if present). During personalization proper, information specific to the particular card, such as payment card account number and holder's name, is applied to the card. Again the information may be applied to the card by one or more of printing, embossing, RF communication and/or magnetic storage on the card mag stripe. The personalization step may, in accordance with conventional practices, be performed by standard automated equipment.

At 606, the protective label 106 may be adhered to the front surface of the card. This also may be done by standard equipment operating in a conventional manner. As has been stated above, it is preferable that the label be of a standard size customarily applied to payment cards, and that the label be applied to a customary standard location on the card. The label may be positioned so as to substantially shield the card antenna from RF radiation and thus protect the card from unauthorized reading.

At 608, the rear surface of the card—with the protective label in place on the front surface of the card—is adhered to the backing sheet. Again this may be done in a conventional manner. At 610 the backing sheet, with the card and the protective label, is inserted by conventional equipment into an envelope. At 612, the envelope (including backing sheet, card, label) is mailed to the intended recipient (i.e., to the prospective card holder).

There has been described hereinabove a preferred embodiment in which the proximity payment card antenna is sized and positioned so as to accommodate standard card fulfillment processing, including application of a label that is standard in size (though the label departs from the conventional by having a shielding layer incorporated therein). However, alternative embodiments are possible, and may be preferred in the event that it is desired not to reduce the size of the antenna, or not to reduce the size of the antenna as much, relative to the conventional antenna configuration. For example, if the antenna is in the conventional configuration that is substantially co-extensive with the card body, then a protective label may be used that also is substantially co-extensive with the card body. That is, the label in this embodiment may be quite a bit larger than the label conventionally applied to provide activation instructions, and may substantially cover the entire face of the card. In other embodiments, the antenna may be somewhat larger than as described in conjunction with FIG. 3, but less extensive than the conventional antenna size. In this case, the label may be larger than the standard size label described above, but need not cover the entire card surface.

It would also be possible to change the shape of the antenna (e.g., the length to width ratio) relative to antennas previously described herein, and to adapt the shape of the protective label accordingly. For example, the long dimension of the antenna may be quite a bit smaller than the antennas described above.

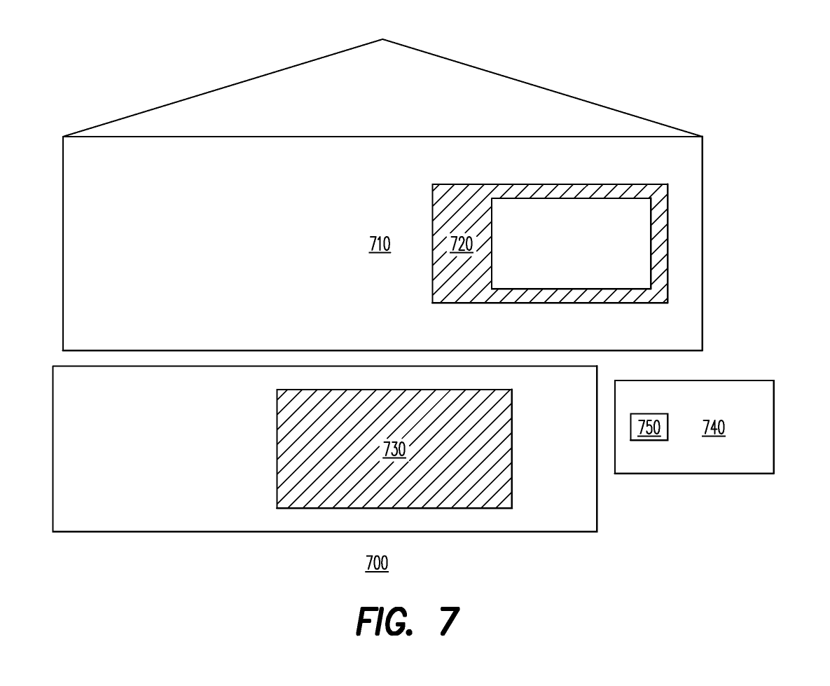

According to an embodiment of the present invention as depicted in FIG. 7, and in accordance with aspects of the present invention, contactless smart cards for payment applications are sent to cardholders enclosed in mailers with RF-shielding, which prevents external radio frequency waves from penetrating the mailer and activating or communicating with the enclosed cards. An exemplary mailer 700 may include a conventional paper envelope 710 and/or paper or cardboard insert 720 to which the proximity, contactless or smart card 740 is tacked onto or attached. RF-shielding material 730 is disposed on paper envelope 710, for example, on interior surfaces proximate to the enclosed card. Alternatively or additionally, RF-shielding material 730 may be disposed on insert 720. RF shielding material 730 may be any suitable material that interferes with the transmission of RF frequency waves. The suitable RF shielding materials may, for example, include conductive inks, metallic films or paper, wire screens, and wire mesh pouches. In some cases, RF-shielding material 730 may simply be a metallic adhesive (e.g., a conductive rubber cement) that can be used to tack the enclosed smart card in position. It will be understood that according to the present invention, RF-shielding material 730 is selected and its geometrical disposition is designed based on known electromagnetic effects (e.g., skin depth) so that it (RF-shielding material 730) effectively interferes with RF signals to or from the on-card chip 750. Thus, the inventive mailer prevents unauthorized detection or reading of the enclosed card.

The principles taught herein have heretofore been described in the context of proximity payment cards. Nevertheless, these teachings are also applicable to cards or the like issued by transportation systems (e.g., mass transit systems) for access to the transportation systems; to cards used to identify the holder for purposes apart from or in addition to transaction payments; and to so-called electronic passports (also known as RFID-enabled passports). As used herein and in the appended claims the term “identification card” refers to a card-shaped object that serves as one or more of a proximity payment card, a transportation card, an identification card and/or an RFID-enabled passport. The term “transportation card” refers to a card or similar device used to pay, or confirm or evidence payment of, a charge for using a transportation system. The term “RFID-enabled passport” refers to an internationally recognized travel document that includes an IC and an antenna and communicates with a terminal by a wireless communication technique.

The present invention may also be applied to identification cards that are of a different size than the ID-1 standard size.

The above description and/or the accompanying drawings are not meant to imply a fixed order or sequence of steps for any process referred to herein; rather any process may be performed in any order that is practicable, including but not limited to simultaneous performance of steps indicated as sequential.

As used herein and in the appended claims, the term “embedded” encompasses being completely or only partially embedded.

As used herein and in the appended claims, the term “generally rectangular” includes a rectangle having rounded corners.

Although the present invention has been described in connection with specific exemplary embodiments, it should be understood that various changes, substitutions, and alterations apparent to those skilled in the art can be made to the disclosed embodiments without departing from the spirit and scope of the invention as set forth in the appended claims.

What is claimed is:

1. An article of manufacture, comprising:
a mailing envelope;
a letter inside the mailing envelope;
a contactless payment card attached to the letter; and
a conductive ink or metallic area on at least one of the letter and the envelope, said conductive ink or metallic area for preventing unauthorized reading of the contactless payment card.

2. The article of manufacture of claim 1, wherein the conductive ink or metallic area is on the letter.

3. The article of manufacture of claim 1, wherein the conductive ink or metallic area is on the envelope.

4. The article of manufacture of claim 1, wherein the contactless payment card is a credit card.

5. The article of manufacture of claim 1, wherein the conductive ink or metallic area interferes with an RF signal directed to the contactless payment card.

6. An article of manufacture, comprising:
a mailing envelope;
a letter inside the mailing envelope;
a contactless payment card attached to the letter; and
a conductive ink on at least one of the letter and the envelope, said conductive ink for preventing unauthorized reading of the contactless payment card.

7. The article of manufacture of claim 6, wherein the conductive ink is on the letter.

8. The article of manufacture of claim 6, wherein the conductive ink is on the envelope.

9. The article of manufacture of claim 6, wherein the contactless payment card is a credit card.

10. The article of manufacture of claim 6, wherein the conductive ink interferes with an RF signal directed to the contactless payment card.

11. An article of manufacture, comprising:
a mailing envelope;
a letter inside the mailing envelope;
a contactless payment card attached to the letter; and
a metallic area on at least one of the letter and the envelope, said metallic area for preventing unauthorized reading of the contactless payment card.

12. The article of manufacture of claim 11, wherein the metallic area is on the letter.

13. The article of manufacture of claim 11, wherein the metallic area is on the envelope.

14. The article of manufacture of claim 11, wherein the contactless payment card is a credit card.

15. The article of manufacture of claim 11, wherein the metallic area interferes with an RF signal directed to the contactless payment card.
